(19) United States
(12) Patent Application Publication
(10) Pub. No.: US 2014/0167136 A1
(43) Pub. Date: Jun. 19, 2014

(54) Charge Trapping Device with Improved Select Gate to Memory Gate Isoloation

(71) Applicant: SPANSION LLC, Sunnyvale, CA (US)

(72) Inventors: Mark RAMSBEY, Sunnyvale, CA (US); James Pak, Sunnyvale, CA (US)

(73) Assignee: Spansion LLC, Sunnyvale, CA (US)

(21) Appl. No.: 13/715,729

(22) Filed: Dec. 14, 2012

(51) Int. Cl. H01L 29/792; H01L 29/66

(52) U.S. Cl. CPC H01L 29/792; H01L 29/66833
USPC 257/324; 438/591

(57) ABSTRACT

Embodiments described herein generally relate to charge-trapping memory with improved isolation between a select gate and a memory gate. The isolation is improved because the charge trapping layer is not present in the junction between the select gate and the memory gate. The methods described herein additionally allow insulation to be disposed between the select gate and the memory gate.

### BACKGROUND

1. Technical Field

The embodiments described herein generally relate to non-volatile memory, such as charge trapping memory.

2. Background

A Flash memory permits stored data to be retained even if power to the memory is removed. A Flash memory cell stores data either by storing electrical charge in an electrically isolated floating gate of a field effect transistor (FET) or by storing electrical charge in a dielectric layer underlying a control gate of a FET. The stored electrical charge controls the threshold of the FET, thereby controlling the memory state of the Flash memory cell.

Conventionally, a Flash memory cell is programmed using drain side hot carrier injection to inject charge carriers either onto a floating gate or into charge trapping sites in a dielectric layer underlying a control gate. High drain and gate voltages are used to speed up the programming process. Thus, the FET in the Flash memory cell conducts a high current during programming, which is undesirable in low voltage and low power applications. A split-gate cell is a type of Flash memory cell in which a select gate is placed adjacent a memory gate. A split gate cell provides lower current during hot-carrier-based programming operation. During the programming of the split-gate cell, the select gate is biased at a relatively low voltage, and only the memory gate is biased at the high voltage to provide the vertical electric field necessary for hot-carrier injection. Since the acceleration of the carriers takes place in the channel region mostly under the select gate, the relatively low voltage on the select gate above that region results in more efficient carrier acceleration in the horizontal direction compared to the conventional memory cell. That makes the hot-carrier injection more efficient with lower current and lower power consumption during the programming operation. A split-gate cell may be programmed using techniques other than hot-carrier injection, and depending on the technique, any advantage over the conventional memory cell during the programming operation may vary.

Fast read time is another advantage of the split-gate cell. Because the select gate is in series with the memory gate, the erased state of the memory gate can be near or in depletion mode (i.e., threshold voltage, Vt, less than zero volt). Even when the erased memory gate is in such depletion mode, the select gate in the off state prevents the channel from conducting substantial current. With the threshold voltage of the erase state at or below zero, the threshold voltage of the programmed state does not need to be very high while still providing a reasonable read margin between the erased and the programmed states. The resulting voltages applied to both the select gate and the memory gate in read operation are less than or equal to the supply voltage. Therefore, not having to pump the supply voltage to a higher level makes the read operation faster.

It is common to monolithically incorporate multiple types of field-effect devices on the same substrate as memory cells. Those non-memory devices perform, for example, decoding, charge-pumping, and other functions related to memory operations. The substrate may also include non-memory devices to provide functions that are not related to memory operations. Such non-memory devices incorporated on the same substrate as the memory cells may include transistors tailored for high-speed operations, while other transistors are tailored for handling high operating voltages. Integrating the processing of memory cells, such as a split-gate memory cell, with the processing of one or more types of non-memory transistors on the same substrate is challenging as each requires different fabrication parameters. Accordingly, there is a need for device and methods for integrating a memory cell and other devices on the same substrate to facilitate improved cost, performance, reliability, or manufacturability.

### BRIEF SUMMARY

It is desirable to obviate or mitigate at least one of the problems, whether identified herein or elsewhere, or to provide an alternative to existing apparatuses or methods.

In an embodiment, a method of fabricating a semiconductor device. A dielectric is disposed on a substrate. A select gate is formed on the dielectric. A charge trapping layer is disposed on at least one region of the substrate adjacent to the select gate and on two sidewalls of the select gate. The charge trapping layer is removed from the two sidewalls of the select gate, while leaving the charge trapping layer on the at least one adjacent region. A memory gate is on the charge trapping layer on the at least one adjacent region.

In an embodiment, a semiconductor device includes a memory region, a first substrate region, and a second substrate region. There are first gates in the first substrate region. There are second gates in the second substrate region. There are select gates in the memory region. There are memory gates in the memory region, with each memory gate formed adjacent to a corresponding select gate. In the embodiment, sidewalls of the memory gates are older than (i.e., formed before) sidewalls of the second gates.

In an embodiment, a semiconductor device includes a select gate. There is a memory gate adjacent to the select gate. There is a charge trapping layer under the memory gate but not under the select gate or on a sidewall thereof. In this semiconductor device, a thickness of the charge trapping layer is substantially uniform adjacent the select gate and along the substrate. Additionally, the select gate has a rectangular cross section in a plane perpendicular to a junction between the memory gate and the select gate.

These and other advantages and features will become readily apparent in view of the following detailed description of embodiments of the invention. Note that the Summary and Abstract sections may set forth one or more, but not all exemplary embodiments of the present invention as contemplated by the inventor(s). It is to be appreciated that the Detailed Description section, and not the Summary and Abstract sections, is intended to be used to interpret the claims.

### BRIEF DESCRIPTION OF THE DRAWINGS/FIGURES

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 illustrates an example of a split-gate non-volatile memory cell, according to an embodiment.

FIG. 2 illustrates an example circuit diagram of memory cell including connections to various metal layers in a semiconductor device, according to an embodiment.

FIG. 3 illustrates an example semiconductor device that includes both memory and peripheral circuitry embedded in the same substrate, according to an embodiment.

FIGS. 4A-4C illustrate a semiconductor device in various stages of manufacturing, according to an embodiment.

FIGS. 5A-5D illustrate a semiconductor device in various stages of manufacturing, according to an embodiment.

FIGS. 6A-6C illustrate a semiconductor device in various stages of manufacturing, according to an embodiment.

FIGS. 7A-7F illustrate a semiconductor device in various stages of manufacturing, according to an embodiment.

FIGS. 8A-8C illustrate cross sections of various semiconductor devices.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Before describing the various embodiments in more detail, further explanation shall be given regarding certain terms that may be used throughout the descriptions.

The term “etch” or “etching” is used herein to generally describe a fabrication process of patterning a material, such that at least a portion of the material remains after the etch is completed. For example, it should be understood that the process of etching silicon involves the steps of patterning a masking layer (e.g., photoresist or a hard mask) above the silicon, and then removing the areas of silicon no longer protected by the masking layer. As such, the areas of silicon protected by the mask would remain behind after the etch process is complete. However, in another example, etching may also refer to a process that does not use a mask, but still leaves behind at least a portion of the material after the etch process is complete.

The above description serves to distinguish the term “etching” from “removing.” When etching a material, at least a portion of the material remains behind after the process is completed. However, “removing” is considered to be a broad term that may incorporate etching.

During the descriptions herein, various regions of the substrate upon which the field-effect devices are fabricated are mentioned. It should be understood that these regions may exist anywhere on the substrate and furthermore that the regions may not be mutually exclusive. That is, in some embodiments, portions of one or more regions may overlap. Although up to three different regions are described herein, it should be understood that any number of regions may exist on the substrate and may designate areas having certain types of devices or materials. In general, the regions are used to conveniently describe areas of the substrate that include similar devices and should not limit the scope or spirit of the described embodiments.

The terms “deposit” or “dispose” are used herein to describe the act of applying a layer of material to the substrate. Such terms are meant to describe any possible layer-forming technique including, but not limited to, thermal growth, sputtering, evaporation, chemical vapor deposition, epitaxial growth, electroplating, etc.

The term “substrate” as used throughout the descriptions is most commonly thought to be silicon. However, the substrate may also be any of a wide array of semiconductor materials such as germanium, gallium arsenide, indium phosphide, etc. In other embodiments, the substrate may be electrically non-conductive such as a glass or sapphire wafer.

The term “poly” as used throughout the descriptions is most commonly thought to be polycrystalline silicon. Poly comprises multiple small crystals, as opposed to being a single monocrystal. Poly can be doped, or may have metal or a metal silicide deposited over it.

“Poly” in this application is used as one example of a gate conductor. Other conductors may be used to form the gates, for example metals, alloys other doped semiconductors or conducting materials as would become apparent to a person having ordinary skill in the art. The use of “poly” in the description of the embodiments is not to be limiting.

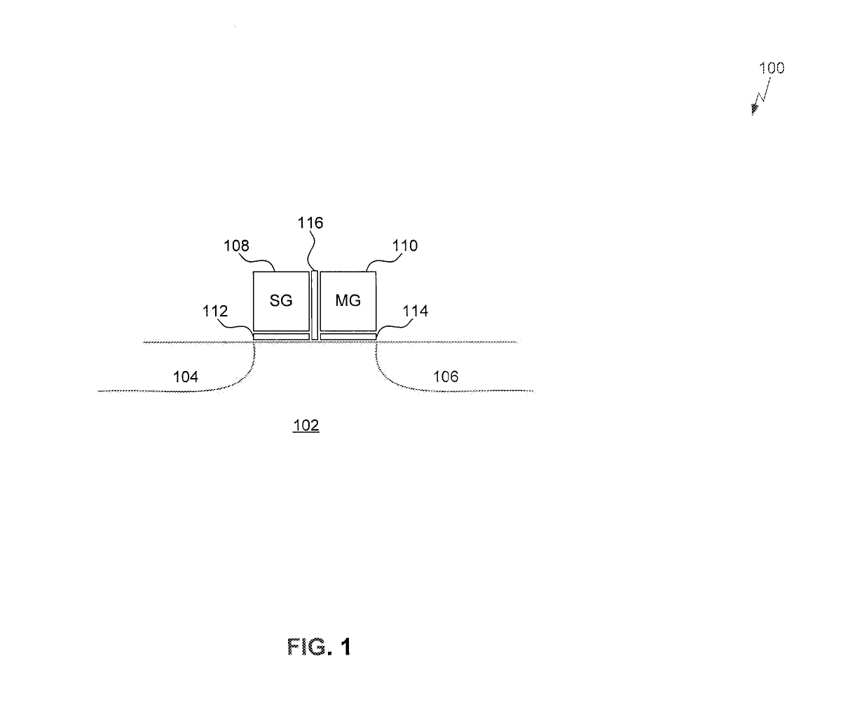

FIG. 1 illustrates an example of a split-gate non-volatile memory cell 100 according to an embodiment. Memory cell 100 is formed on a substrate 102, such as silicon. Substrate 102 is commonly p-type or a p-type well while a first doped source/drain region 104 and a second doped source/drain region 106 are n-type. However, it is also possible for substrate 102 to be n-type while regions 104 and 106 are p-type.

Memory cell 100 includes two gates, a select gate 108 and a memory gate 110. Each gate may be a doped poly layer formed by well known, for example, deposit and etch techniques to define the gate structure. Select gate 108 is disposed over a dielectric layer 112. Memory gate 110 is disposed over a charge trapping dielectric 114 having one or more dielectric layers. In one example, charge trapping dielectric 114 includes a silicon nitride layer sandwiched between two silicon dioxide layers to create a three-layer stack collectively and commonly referred to as “ONO”. Other charge trapping dielectrics may include a silicon-rich nitride film, or any film that includes, but is not limited to, silicon, oxygen, and nitrogen in various stoichiometries. A vertical dielectric 116 is also disposed between select gate 108 and memory gate 110 for electrical isolation between the two gates. In some examples, vertical dielectric 116 and charge trapping dielectric 114 are the same dielectric, while other examples form one dielectric before the other (e.g., they can have different dielectric properties.) As such, vertical dielectric 116 need not include the same film structure as charge trapping dielectric 114. After the gates have been defined, regions 104 and 106 are created by implanting dopants using, for example, an ion implantation technique. Regions 104 and 106 form the source or drain of the split-gate transistor depending on what potentials are applied to each. In split gate transistors, for convenience, region 104 is commonly referred to as the drain, while region 106 is commonly referred to as the source, independent of the relative biases. It is to be understood that this description is meant to provide a general overview of a common split-gate architecture and that, in actual practice, many more detailed steps and layers are provided to form the final memory cell 100.

An example write, read, and erase operation will now be described as it relates to memory cell 100. In order to write a bit in memory cell 100, a positive voltage on the order of 5 volts, for example, is applied to region 106 while region 104 and substrate 102 are grounded. A low positive voltage on the order of 1.5 volts, for example, is applied to select gate 108 while a higher positive voltage on the order of 8 volts, for example, is applied to memory gate 110. As electrons are accelerated within a channel region between the source and drain, some of them will acquire sufficient energy to be injected upwards and get trapped inside charge trapping dielectric 114. This is known as hot electron injection. In one example of charge trapping dielectric 114, the electrons are trapped within a nitride layer of charge trapping dielectric 114. This nitride layer is also commonly referred to as the charge trapping layer. The trapped charge within charge trapping dielectric 114 store the “high” bit within memory cell 100, even after the various supply voltages are removed.

In order to “erase” the stored charge within memory cell 100 and return the state of memory cell 100 to a “low” bit, a positive voltage on the order of 5 volts, for example, is applied to region 106 while region 104 is floated or at a certain bias, and select gate 108 and substrate 102 are typically grounded. A high negative voltage on the order of −8 volts, for example, is applied to memory gate 110. The bias conditions between memory gate 110 and region 106 generate holes through band-to-band tunneling. The generated holes are sufficiently energized by the strong electric field under memory gate 110 and are injected upwards into charge trapping dielectric 114. The injected holes effectively erase the memory cell 100 to the “low” bit state.

In order to “read” the stored bit of memory cell 100, a low voltage is applied to each of the select gate, memory gate, and region 104 in the range between zero and 3 volts, for example, while region 105 and substrate 102 are typically grounded. The low voltage applied to the memory gate is chosen so that it lies substantially equidistant between the threshold voltage necessary to turn on the transistor when storing a “high” bit and the threshold voltage necessary to turn on the transistor when storing a “low” bit in order to clearly distinguish between the two states. For example, if the application of the low voltage during the “read” operation caused substantial current to flow between regions 104 and 106, then the memory cell holds a “low” bit and if the application of the low voltage during the “read” operation does not cause substantial current to flow between regions 104 and 106, then the memory cell holds a “high” bit.

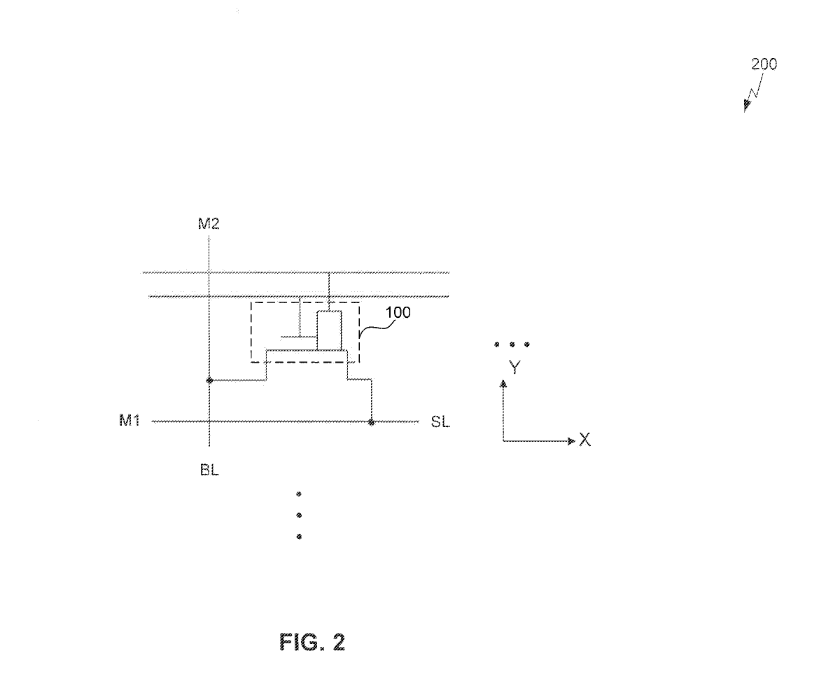

FIG. 2 illustrates an example circuit diagram of memory cell 100 including connections to various metal layers in a semiconductor device. Only a single memory cell 100 is illustrated, however, as evidenced by the ellipses in both the X and Y direction, an array of memory cells may be connected by the various lines running in both the X and Y directions. In this way, one or more memory cells 100 may be selected for reading, writing, and erasing bits based on the bit line (BL) and source line (SL) used.

An example source line (SL) runs along the X direction and is formed in a first metal layer (M1). Source line (SL) may be used to make electrical connection with doped region 106 of each memory cell 100 along a row extending in the X direction.

An example bit line (BL) runs along the Y direction and is formed in a second metal layer (M2). Bit line (BL) may be used to make electrical connection with doped region 104 of each memory cell 100 along a column extending in the Y direction.

It is to be understood that the circuit connections shown in FIG. 2 are only exemplary and that the various connections could be made in different metal layers than those illustrated. Furthermore, although not depicted, memory cells 100 may be arrayed in the Z direction as well formed within multiple stacked layers.

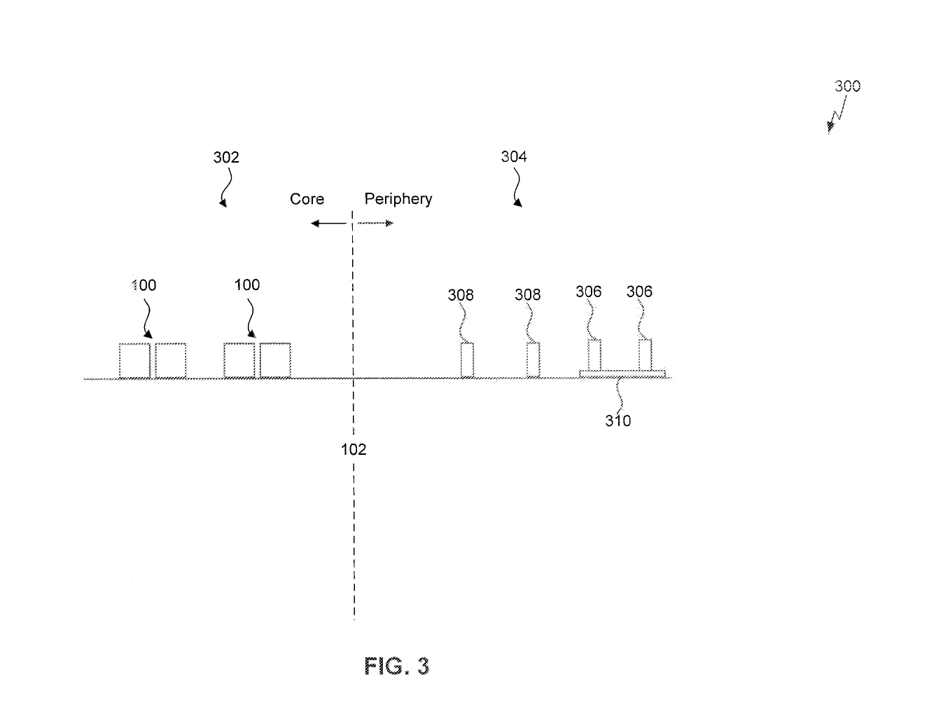

FIG. 3 illustrates an example semiconductor device that includes both memory and peripheral circuitry in the same substrate. In this example, substrate 102 includes a core region 302 and a periphery region 304. Core region 302 includes a plurality of memory cells 100 that may operate similarly to those previously described. It should be understood that the cross-section of FIG. 3 is only exemplary, and that core region 302 and periphery region 304 may be located in any area of substrate 102 and may be made up of various different regions. Furthermore, core region 302 and periphery region 304 may exist in the same general area of substrate 102.

Periphery region 304 may include integrated circuit components such as resistors, capacitors, inductors, etc., as well as transistors. In the illustrated embodiment, periphery region 304 includes a plurality of high-voltage transistors 306 and low-voltage transistors 308. In one example, high-voltage transistors 306 exist in a separate region of substrate 102 than low-voltage transistors 308. High-voltage transistors 306 are capable of handling voltages up to 20 volts in magnitude, for example, while low-voltage transistors 308 operate at a faster speed, but cannot operate at the same high voltages as high-voltage transistors 306. In an embodiment, low voltage transistors 308 are designed to have a shorter gate length than high voltage transistors 306. High-voltage transistors 306 are commonly characterized as having a thicker gate dielectric 310 than the gate dielectric of low-voltage transistors 308.

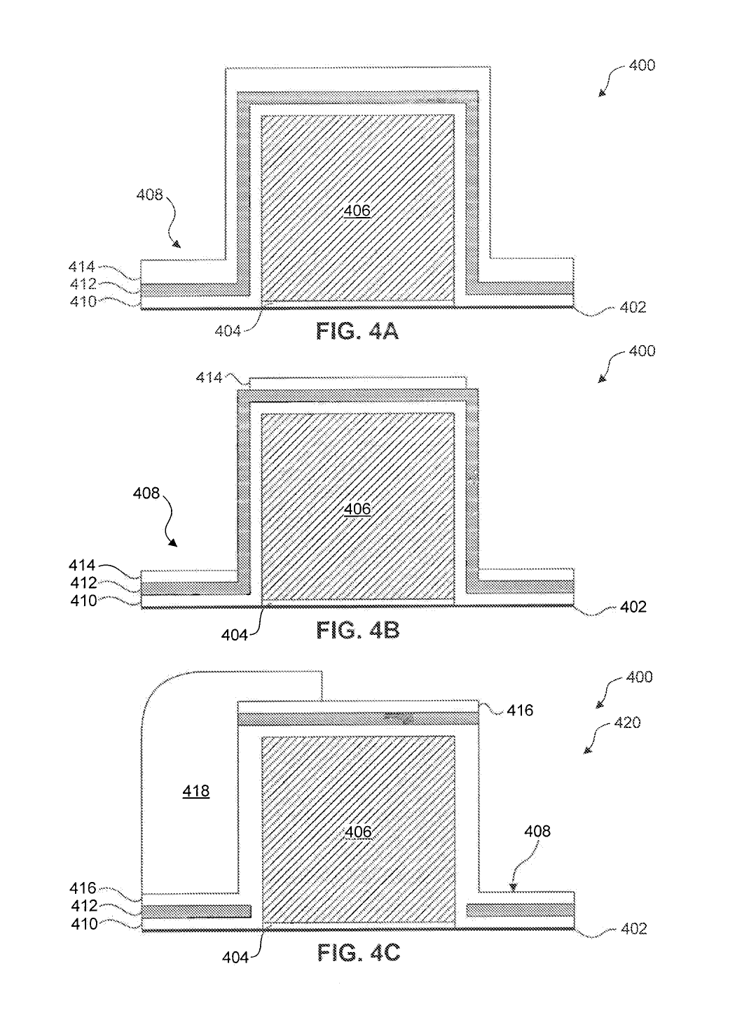

FIGS. 4A-4C, 5A-5D, 6A-6C and 7A-7F illustrate fabrication process flows for semiconductor devices 400. It should be understood that the various layers are not necessarily drawn to scale and that other processing steps may be performed as well between the steps illustrated as would be understood by one skilled in the art given the description herein.

FIG. 4A illustrates a step in the method of fabrication of an intermediate semiconductor device 400. The semiconductor device 400 has a substrate 402 (represented simply by a solid line for ease). To form the semiconductor device 400 of FIG. 4A on the substrate 402, the method disposes a dielectric layer 404 on the substrate 402. The method disposes a poly layer and patterns it to form select gate 406 on the dielectric layer 404. Optionally, the method removes the dielectric layer 404 that is unprotected by the select gate 406. The method forms a charge trapping dielectric 408 on the substrate 402 such that it covers the dielectric layer 404 and the select gate 406. Charge trapping dielectric 408 comprises three sub layers 410, 412 and 414. The bottom layer of oxide 410 is preferably between 2 and 10 nanometers (nm) thick. The charge trapping layer of nitride 412 is preferably between 4 and 15 nm thick. The charge trapping layer 412 may optionally be silicon rich nitride. The top layer of oxide 414 is preferably 50 nm thick on top of the select gate 406 and 25 nm thick on a sidewall of the select gate 406. One way to create the top layer of oxide 414 is to deposit a 50 nm thick layer of silane oxide with 50% step coverage. The top oxide 414 can be used as a sacrificial nonconformal masking layer, hence the deposition with a 50% step coverage. The top layer of oxide 414 is an example of a nonconforming masking layer that is thicker on a region of the substrate 402 adjacent to the select gate 406 than on the two sidewalls of the select gate 406. The top layer of oxide 414 is twice as thick on the adjacent regions of the substrate 402 and the top of the select gate 406 than on the two sidewalls of the select gate 406. Disposing the bottom layer of oxide 410 before the nitride layer 412 is an example of disposing an insulator 410 on the two sidewalls of the select gate 406 before disposing a charge trapping layer 412.

FIG. 4B illustrates a later step in the method of fabrication to form an intermediate semiconductor device 400. The method removes a significant portion of the top oxide layer 414 by an isotropic etch, such as a 40 nm etch. Optionally, in one embodiment, a spin-on resist may be disposed followed by an oxide etch to remove the top oxide 414 from the top of the select gate 406.

FIG. 4C illustrates a later step in the method of fabrication to form an intermediate semiconductor device 400. The method performs a nitride etch, removing the nitride layer 412 from the sidewalls of the select gate 406, such that there is not a charge trapping layer 412 on the sidewalls of the select gate 406. The method disposes a new top oxide layer 416. The new top oxide layer 416 may be created through thermal growth or through an in-situ steam generation process. The top oxide 416 is between 2 nm and 10 nm thick on the substrate regions adjacent to the select gate 406, and between 6 nm and 30 nm thick on the sidewalls of the select gate. Low pressure chemical vapor deposition (LPCVD) can be used to deposit the top oxide layer 416.

One advantage to keeping the isolation layer between the memory gate 418 and the select gate 406 as thin as possible is because then the memory gate 418 and the select gate 406 can better control the channel region at that interface area. In another embodiment, where higher voltages are to be used for programming or erase operations, it may be desirable to have the sidewall oxide physically and electrically thicker than the nitride layer 412, such that the thick sidewall oxide has a higher breakdown voltage than the nitride layer 412.

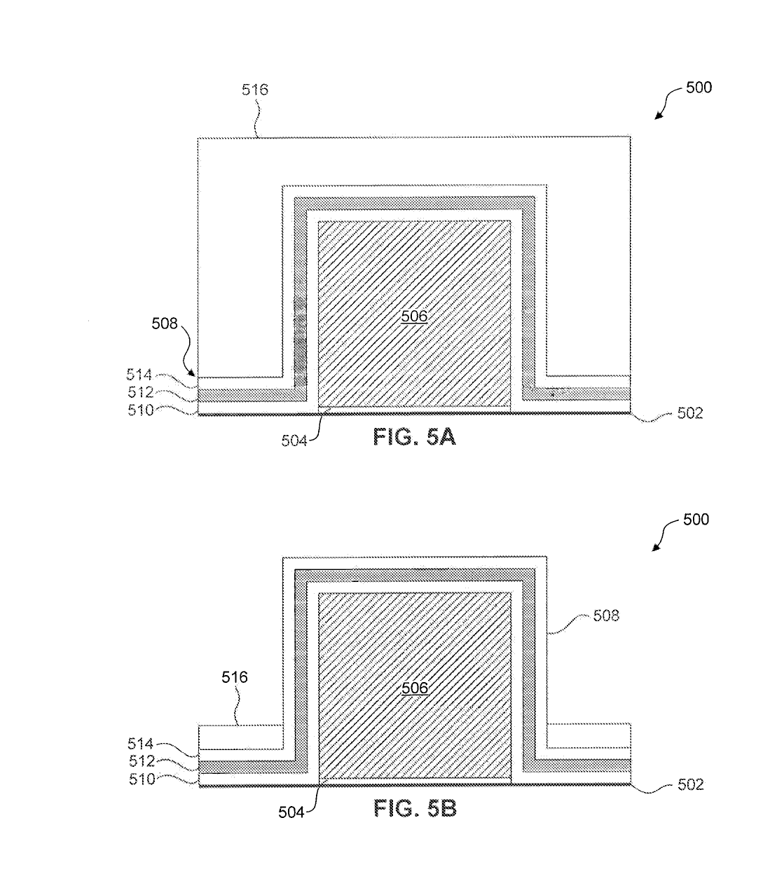

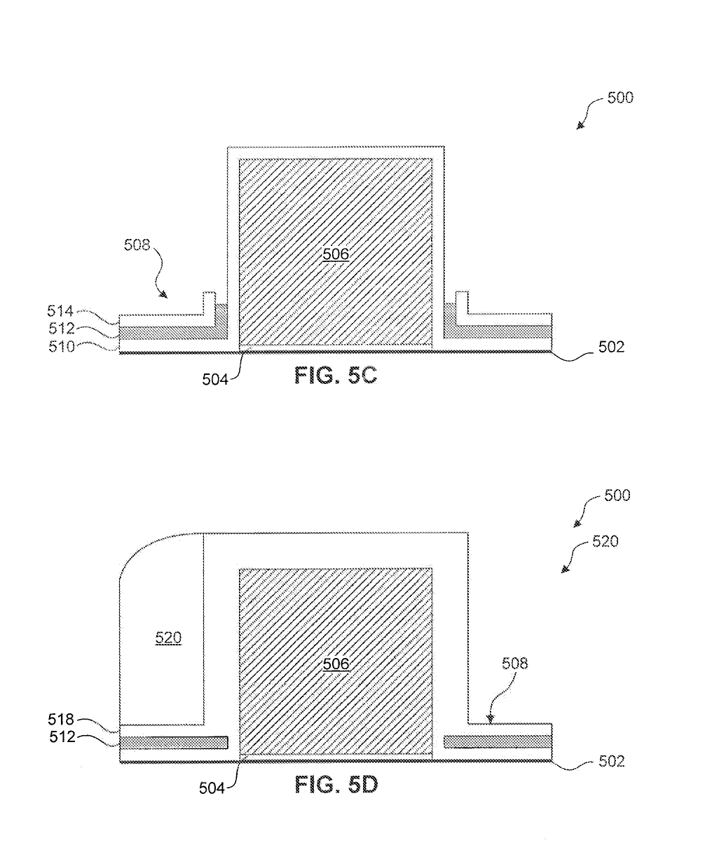

FIG. 5A illustrates a step in the method of fabrication of an alternative intermediate semiconductor device 500. The method disposes a dielectric layer 504 on the substrate 502. The method disposes a poly layer and patterns it to form select gate 506 on the dielectric layer 504. Optionally, the method removes the dielectric layer 504 that is unprotected by the select gate 506. The method forms a charge trapping dielectric 508 on the substrate 502 such that it covers the dielectric layer 504 and the select gate 506. The nitride layer 512 may optionally be silicon rich nitride. The method disposes a planarizing layer 516. The planarizing layer 516 can be made of amorphous carbon or a thick material deposited as a liquid and cured, for example resist, Bottom Antireflective Coating (BARC) or Spin on Glass (SOG).

FIG. 5B illustrates a later step in the method of fabrication to form an alternative intermediate semiconductor device 500. The method performs an etchback to remove most of the planarizing layer 516. One way to perform the etchback is an endpoint plus timed overetch, though other methods can be used as would become apparent to a person having ordinary skill in the art based on the disclosure herein.

FIG. 5C illustrates a later step in the method of fabrication to form an alternative intermediate semiconductor device 500. The method removes the top layer of oxide 514 from the sidewalls and the top of the select gate 506, i.e., the areas left unprotected by the planarizing layer 516. The method performs a nitride etch to etch the nitride layer 512. One way to etch the nitride layer 512 is to use a timed etch to remove the nitride layer 512. The method strips the planarizing layer 516.

FIG. 5D illustrates a later step in the method of fabrication to form an alternative intermediate semiconductor device 500. Optionally, the method removes all or part of the remaining top layer of oxide 514 by known methods. The method disposes a new top oxide layer 518. The method can create a new top oxide layer 518 through LPCVD deposition, thermal growth or through an in-situ steam generation process. The method forms a memory gate 520. The memory gate 520 can be formed by disposing a layer of poly over the select gate 506 and the adjacent regions of the substrate 502 and etching. The addition of the memory gate 520 completes the memory cell 522.

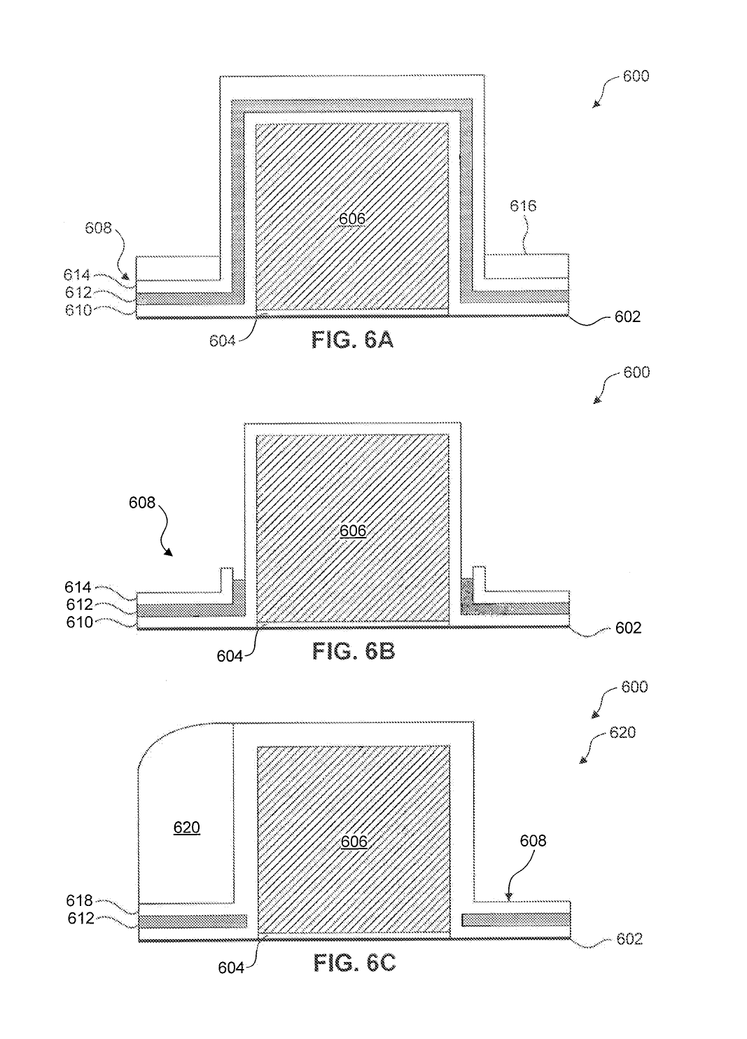

FIG. 6A illustrates a step in the method of fabrication of an alternative intermediate semiconductor device 600. The semiconductor device 600 has a substrate 602. The method disposes a dielectric layer 604 on the substrate 602. The method disposes a poly layer and patterns it to form select gate 606 on the dielectric layer 604. Optionally, the method removes the dielectric layer 604 that is unprotected by the select gate 606. The method forms a charge trapping dielectric 608 on the substrate 602 so as to cover the dielectric layer 604 and the select gate 606. The nitride layer 612 may optionally be silicon rich nitride. The method disposes a thin non-conformal film, for example spin-on resist 616.

FIG. 6B illustrates a later step in the method of fabrication to form an alternative intermediate semiconductor device 600. The method removes the top layer of oxide 614 from the sidewalls and the top of the select gate 606 (i.e., the areas left unprotected by the film 616). The method performs a nitride etch to etch the nitride layer 612. One way to etch the nitride layer 612 is to use a timed etch to remove the nitride layer 612. The method strips the film 616.

FIG. 6C illustrates a later step in the method of fabrication to form an alternative intermediate semiconductor device 600. Optionally, the method removes all or part of the remaining top layer of oxide 614. The method disposes a new top oxide layer 618. The new top oxide layer 618 may be created through LPCVD deposition, thermal growth or through an in-situ steam generation process. The method forms a memory gate 620. The memory gate 620 can be formed by disposing a layer of poly over the select gate 606 and the adjacent regions of the substrate 602 and etching. The addition of the memory gate 620 completes the memory cell 622.

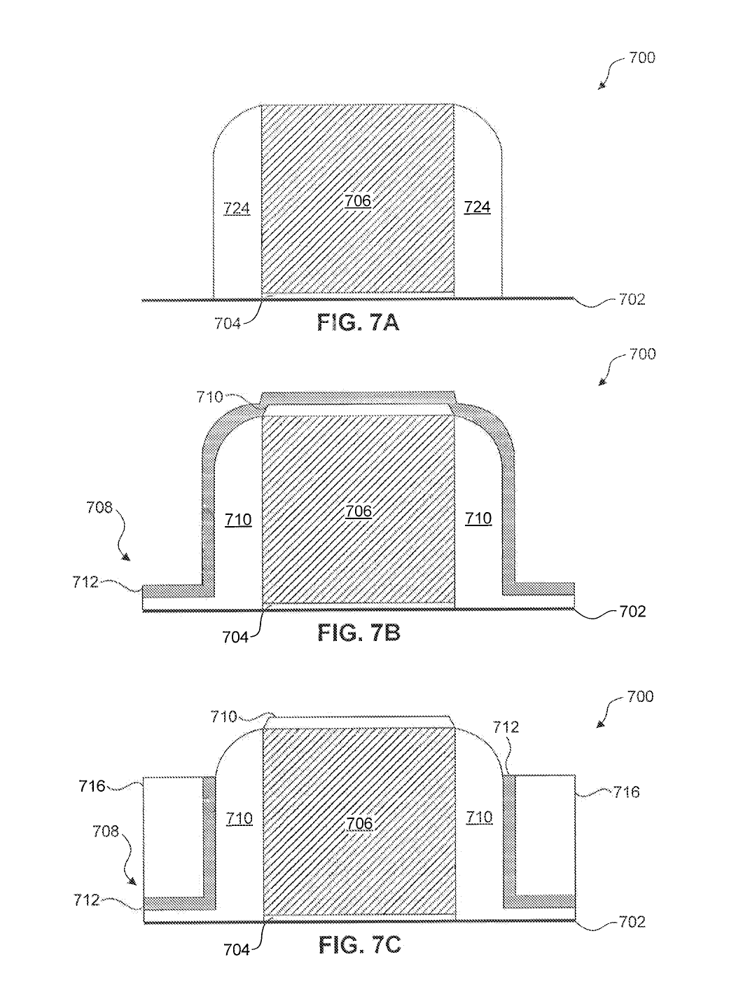

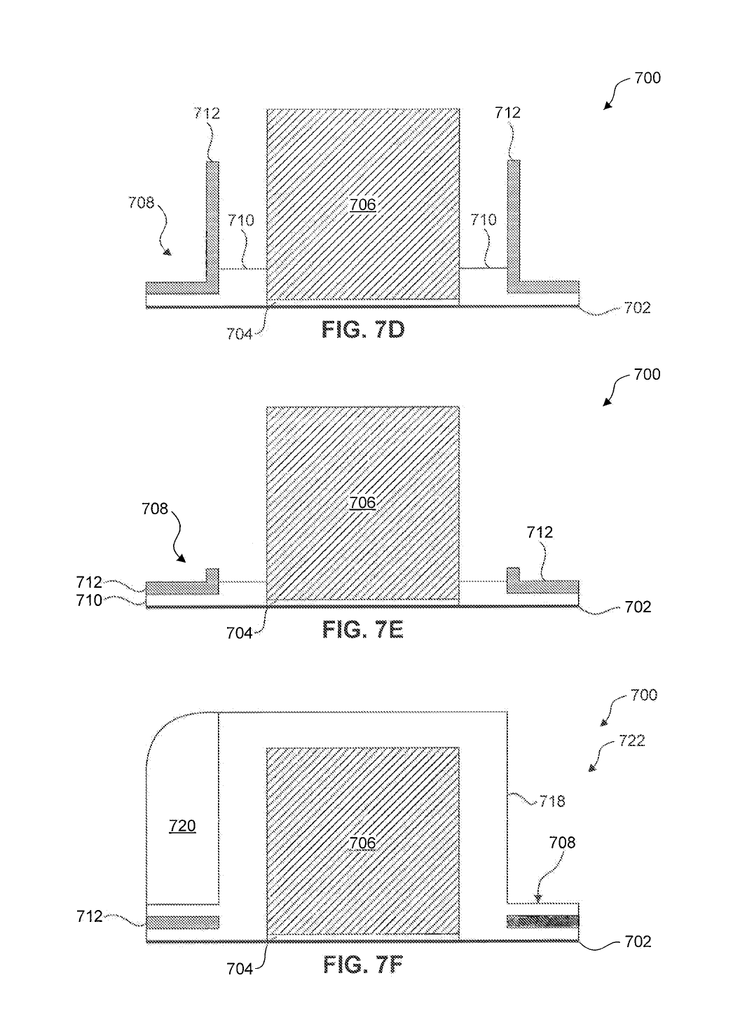

FIG. 7A illustrates a step in the method of fabrication of an alternative intermediate semiconductor device 700. The semiconductor device 700 has a substrate 702. The method disposes a dielectric layer 704 on the substrate 702. The method disposes a poly layer and patterns it to form select gate 706 on the dielectric layer 704. The method grows an oxide spacer as a first layer of oxide 724. In one embodiment, the first layer of oxide 724 can be grown from TEOS as a source gas. The method performs an isotropic etch on the first layer of oxide 724.

FIG. 7B illustrates a later step in the method of fabrication to form an alternative intermediate semiconductor device 700. The method disposes a bottom layer of oxide 710, for example through LPCVD deposition or thermally growth. The method deposits a layer of nitride 712 above the bottom layer of oxide 710.

FIG. 7C illustrates a later step in the method of fabrication to form an alternative intermediate semiconductor device 700. The method disposes a resist coat 716. The method performs an etchback on the exposed sections of the semiconductor device 700. The method performs a nitride etch of the nitride in the exposed nitride layer 712.

FIG. 7D illustrates a later step in the method of fabrication to form an alternative intermediate semiconductor device 700. The method performs an etch to remove the upper section of the bottom oxide layer 710. The method strips the resist coat 716.

FIG. 7E illustrates a later step in the method of fabrication to form an alternative intermediate semiconductor device 700. The method performs a nitride etch to remove the vertical sections of the nitride layer 712. Optionally, the method removes the remaining top layer of oxide 714. The method can optionally remove a small portion of the bottom layer of oxide 710.

FIG. 7F illustrates a later step in the method of fabrication to form an alternative intermediate semiconductor device 700. The method disposes a new top oxide layer 718. The new top oxide layer 718 may be created through deposition, thermal growth or through an in-situ steam generation process. Thermal oxidation would grow sidewall oxide but very little oxide on top of the nitride 712. The method forms a memory gate 720. The memory gate 720 can be formed by disposing a layer of poly over the select gate 706 and etching. The addition of the memory gate 720 completes the memory cell 722.

Further manufacturing steps can be performed following those shown in FIGS. 4C, 5D, 6C and 7F to complete the memory cell. The memory cells can be one of many memory cells in an array. Further manufacturing steps may be taken to connect bit lines, word lines, to create drain regions and source regions and other steps to create computer readable memory. The region of the substrate on which the memory gate is formed is an example of a region of the substrate adjacent to the select gate.

One advantage of the semiconductor devices of FIGS. 4C, 5D, 6C and 7F is that they are substantially free of a charge trapping layer on the sidewalls of the select gate; in other words, the sidewalls of the select gate have little to no charge trapping characteristics. The lack of charge trapping characteristics on the sidewalls improves isolation between a select gate and an adjacent memory gate.

In FIGS. 4C, 5D, 6C and 7F, the semiconductor devices are examples of a thickness of the charge trapping layer being substantially uniform adjacent the select gate and along the substrate. One advantage to a charge trapping layer that does not taper off near the select gate is improved performance of the memory cell because the charge trapping layer is closer to the select gate. One reason that the charge trapping layers of FIGS. 4C, 5D, 6C and 7F are uniform is that these charge trapping layers were disposed in a manner that disposed a substantially similar amount of nitride, or other charge trapping layer, as opposed to a method that disposes significantly less nitride near a corner of a select gate.

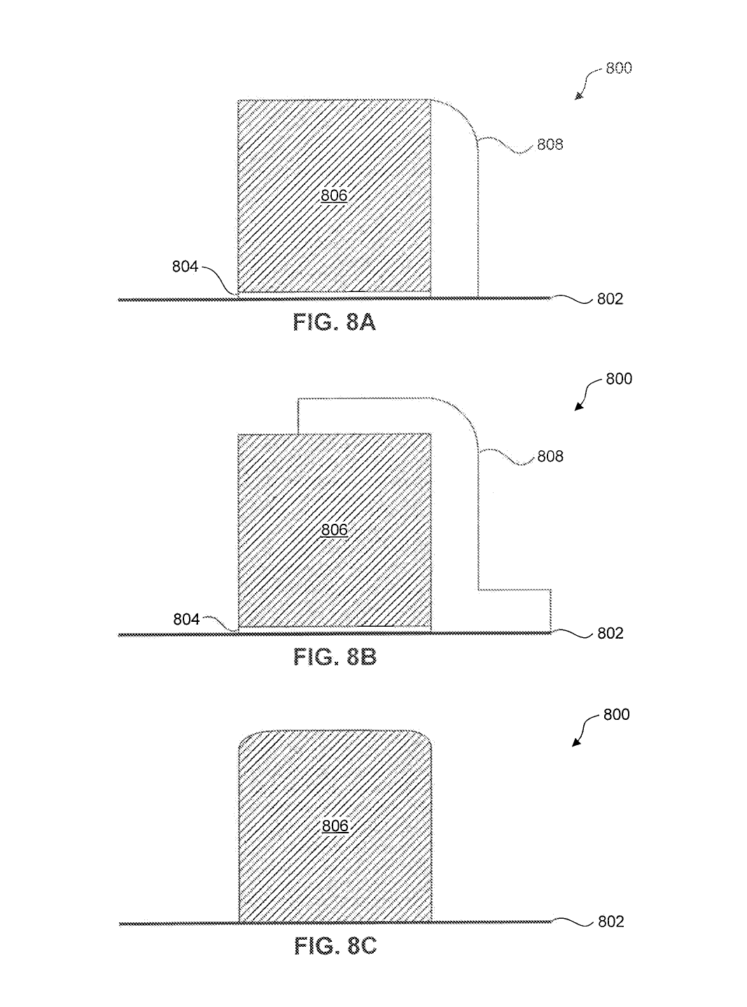

FIGS. 8A-8C are instructive to understand the term “rectangular cross section.” FIGS. 8A-8C illustrate cross sections in a plane perpendicular to a junction between a memory gate 808 and a select gate 806. In general, a rectangular cross section results when a material, such as poly, is disposed on a flat surface, such as a substrate 802, and then patterned and etched. The select gates 806 in FIGS. 8A and 8B are examples of rectangular cross sections. The select gate 806 of FIG. 8C is also a rectangular cross section even though the top corners are rounded. The term rectangular cross section is understood to be an approximate term, and encompasses variations due to manufacturing, such as those depicted in FIG. 8C.

In contrast, the memory gate 808 of FIG. 8A does not have a rectangular cross section because its top is not primarily flat due to the etching used to form the memory gate 808.

The memory gate 808 of FIG. 8B does not have a rectangular cross section. It is primarily ‘S’ shaped due to its coverage on a portion of both the top and side of the select gate 806, as well as a portion of the substrate.

While embodiments have been described herein with reference to charge trapping memory, the invention is not limited to these examples. Instead, embodiments of the invention are applicable to other types of computer memory. The invention is useful for both charge-trapping and floating-gate devices. This invention may be implemented with multi-level cells or other multi-bit memory technologies.

Embodiments of the present invention have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A method of fabricating a semiconductor device, comprising:
disposing a dielectric on a substrate;
forming a select gate on the dielectric;
disposing a charge trapping layer on at least one region of the substrate adjacent to the select gate and on two sidewalls of the select gate;
removing the charge trapping layer from the two sidewalls of the select gate, while leaving the charge trapping layer on the at least one adjacent region; and
forming a memory gate on the charge trapping layer on the at least one adjacent region.

2. The method of claim 1, further comprising disposing a nonconforming masking layer on the charge trapping layer on the two sidewalls of the select gate, before the removing step, wherein the nonconforming masking layer is thicker on the at least one adjacent region than on the two sidewalls.

3. The method of claim 1, wherein the removing the charge trapping layer comprises disposing a spin-on layer on the charge trapping layer on the at least one adjacent region, and etching the charge trapping layer from the two sidewalls of the select gate.

4. The method of claim 1, further comprising disposing an insulator on the two sidewalls of the select gate before the disposing the charge trapping layer on the two sidewalls.

5. The method of claim 1, further comprising disposing an insulator on the two sidewalls, wherein a breakdown voltage of the insulator is greater than a breakdown voltage of the charge trapping layer on the at least one adjacent region.

6. The method of claim 1, further comprising disposing an insulator on the two sidewalls, wherein a physical thickness of the insulator is greater than a physical thickness of the charge trapping layer on the at least one adjacent region.

7. The method of claim 1, further comprising disposing an insulator on the two sidewalls, wherein an electrical thickness of the insulator is greater than an electrical thickness of the charge trapping layer on the at least one adjacent region.

8. The method of claim 1, further comprising disposing an insulator on the two sidewalls, wherein the insulator has substantially less charge trapping characteristic than the charge trapping layer on the at least one adjacent region.

9. The method of claim 8, wherein the insulator is a high temperature oxide.

10. The method of claim 1, further comprising forming a first oxide layer on the substrate prior to the charge trapping layer, forming a second oxide layer on the charge trapping layer, wherein the second oxide layer on a top of the select gate is formed approximately twice as thick as the second oxide layer on the two sidewalls.

11. The method of claim 1, wherein the disposing the charge trapping layer comprises disposing the charge trapping layer on a top of the select gate, and wherein a portion of the charge trapping layer remains on the top of the select gate.

12. The method of claim 1, further comprising disposing a dielectric on a top of the select gate.

13. The method of claim 12, farther comprising disposing a charge trapping layer on the dielectric on the top of the select gate.

14. A semiconductor device, comprising:
a select gate;
a memory gate adjacent to the select gate; and
a charge trapping layer under the memory gate but not under the select gate or on a sidewall thereof,
wherein a thickness of the charge trapping layer is substantially uniform adjacent the select gate and along the substrate, and wherein the select gate has a rectangular cross section in a plane perpendicular to a junction between the memory gate and the select gate.

15. The semiconductor device of claim 14, further comprising an insulator between the select gate and the memory gate, wherein the breakdown voltage of the insulator is greater than a breakdown voltage of the charge trapping layer.

16. The semiconductor device of claim 14, further comprising an insulator between the select gate and the memory gate, wherein a physical thickness of the insulator is greater than a physical thickness of the charge trapping layer on at least one region of the substrate adjacent to the select gate.

17. The semiconductor device of claim 14, further comprising an insulator between the select gate and the memory gate, wherein an electrical thickness of the insulator is greater than an electrical thickness of the charge trapping layer on at least one region of the substrate adjacent to the select gate.

18. The semiconductor device of claim 14, further comprising an insulator between the select gate and the memory gate, wherein the insulator has substantially less charge trapping characteristic than the charge trapping layer on at least one region of the substrate adjacent to the select gate.

19. The semiconductor device of claim 18, wherein the insulator is a high temperature oxide.

20. The semiconductor device of claim 14, further comprising a dielectric on a top of the select gate.

21. The semiconductor device of claim 20, further comprising a charge trapping layer on the dielectric on the top of the select gate.

22. The semiconductor device of claim 14, further comprising an insulator between the select gate and the memory gate, wherein the charge trapping layer is adjacent to at least one dielectric, and the insulator has a different thickness than the at least one dielectric.

23. The semiconductor device of claim 14, further comprising an insulator between the select gate and the memory gate, wherein the insulator is approximately 6-30 nanometers thick.

24. The semiconductor device of claim 14, wherein the charge trapping layer is approximately 4-15 nanometers thick and is adjacent to an oxide layer that is approximately 2-10 nanometers thick.

25. The semiconductor device of claim 14, further comprising an insulator on the sidewalls of the select gate and on a top of the select gate.

26. The semiconductor device of claim 14, wherein the memory gate is thinner than the select gate.
